(19) United States
(12) Patent Application Publication
(10) Pub. No.: US 2012/0083134 A1
(43) Pub. Date: Apr. 5, 2012

(54) METHOD OF MITIGATING SUBSTRATE DAMAGE DURING DEPOSITION PROCESSES

(76) Inventors: Hui-Jung WU, Fremont, CA (US); Kay SONG, San Jose, CA (US); Victor LU, Foster City, CA (US); Kie Jin PARK, San Jose, CA (US); Wai-Fan YAU, Los Altos, CA (US)

(21) Appl. No.: 13/234,020

(22) Filed: Sep. 15, 2011

Related U.S. Application Data
(60) Provisional application No. 61/438,912, filed on Feb. 2, 2011.
(60) Provisional application No. 61/388,513, filed on Sep. 30, 2010.

(51) Int. Cl. H01L 21/30; B05C 11/00

(52) U.S. Cl. 438/761; 118/696; 257/E21.211

(57) ABSTRACT

Systems, methods, and apparatus for depositing a protective layer on a wafer substrate are disclosed. In one aspect, a protective layer is deposited over a surface of a wafer substrate using a process configured to produce substantially less damage in the wafer substrate than a first plasma-assisted deposition process. The protective layer is less than about 100 Angstroms thick. A barrier layer is deposited over the protective layer using the first plasma-assisted deposition process.

### CROSS-REFERENCE TO RELATED APPLICATIONS

This application claims benefit under 35 U.S.C. §119(e) to U.S. Provisional Patent Application No. 61/388,513, filed Sep. 30, 2010, and to U.S. Provisional Patent Application No. 61/438,912, filed Feb. 2, 2011, both of which are herein incorporated by reference.

### BACKGROUND

In integrated circuit fabrication, metal lines are often in contact with dielectric layers. For example, a trench in a dielectric layer may be formed and then metal deposited in the trench to form a metal line. It may be desirable to use copper, with its low resistivity, to form these metal lines. Copper, however, due to its diffusivity in a dielectric layer, should not be in direct contact with dielectric layers. Therefore, a barrier layer may be deposited on the dielectric layer before depositing copper to separate the copper from the dielectric layer.

### SUMMARY

Methods, apparatus, and systems for forming a barrier layer are provided. According to various implementations, the methods involve first depositing a protective layer over a surface of a wafer substrate. Then, a barrier layer may be deposited over the protective layer using a plasma-assisted deposition process.

According to one implementation, a method includes depositing a protective layer over a surface of a wafer substrate using a process configured to produce substantially less damage in the wafer substrate than a first plasma-assisted deposition process. The protective layer is less than about 100 Angstroms thick. A barrier layer is deposited over the protective layer using the first plasma-assisted deposition process.

According to another implementation, an apparatus includes a process chamber and a controller. The controller includes program instructions for conducting a process including the operations of (1) depositing a protective layer over a surface of a wafer substrate using a process configured to produce substantially less damage in the wafer substrate than a first plasma-assisted deposition process, and (2) depositing the barrier layer over the protective layer using the first plasma-assisted deposition process. The protective layer is less than about 100 Angstroms thick.

According to another implementation, a non-transitory computer machine-readable medium includes program instructions for control of a deposition apparatus. The instructions include code for (1) depositing a protective layer over a surface of a wafer substrate using a process configured to produce substantially less damage in the wafer substrate than a first plasma-assisted deposition process, and (2) depositing a barrier layer over the protective layer using the first plasma-assisted deposition process. The protective layer is less than about 100 Angstroms thick.

These and other aspects of implementations of the subject matter described in this specification are set forth in the accompanying drawings and the description below.

### BRIEF DESCRIPTION OF THE DRAWINGS

FIG. 1 shows an example of a flow diagram of a method of depositing a barrier layer.

FIG. 2 shows an example of a flow diagram of a method of depositing a barrier layer.

FIG. 3 shows an example of a schematic diagram of a system suitable for atomic layer deposition (ALD) and ion-induced atomic layer deposition (iALD) processes.

### DETAILED DESCRIPTION

In the following detailed description, numerous specific implementations are set forth in order to provide a thorough understanding of the disclosed implementations. However, as will be apparent to those of ordinary skill in the art, the disclosed implementations may be practiced without these specific details or by using alternate elements or processes. In other instances well-known processes, procedures, and components have not been described in detail so as not to unnecessarily obscure aspects of the disclosed implementations.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. The following detailed description assumes the disclosed implementations are implemented on a wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

Some implementations described herein relate to methods, apparatus, and systems for depositing barrier layers in features on a wafer substrate. The disclosed methods are particularly applicable for depositing metal diffusion barrier layers, such as tantalum nitride (TaN) barrier layers, over a dielectric material in features on a wafer substrate. In some implementations of the disclosed methods, a protective layer is first deposited on the dielectric material. Then, TaN is deposited using an ion-induced atomic layer deposition (iALD) or a plasma-enhanced chemical vapor deposition (PECVD) process. The protective layer may protect the dielectric material from damage potentially caused by the iALD or the PECVD process.

iALD processes have the advantage of producing a TaN layer with a higher density and lower resistivity compared to other deposition methods; a higher density of a TaN layer also may give the layer improved properties as a barrier layer. Further, with an iALD process, the properties of the surface of the TaN layer can be engineered, for example, to optimize the adhesion of subsequent layers deposited on the TaN layer.

### Introduction

A commonly used metal barrier layer is tantalum nitride (TaN). Ion-induced atomic layer deposition (iALD) is one process for depositing TaN. iALD is an example of a plasma-assisted deposition process. Another plasma-assisted deposition process is plasma-enhanced chemical vapor deposition (PECVD). iALD processes are described in U.S. Pat. Nos. 6,428,859, 6,416,822, and 7,871,678, all of which are herein incorporated by reference. iALD processes are also described in U.S. patent application Ser. No. 11/520,497, titled “METHOD OF REDUCING PLASMA STABILIZATION TIME IN A CYCLIC DEPOSITION PROCESS,” and filed Sep. 12, 2006, which is herein incorporated by reference.

iALD processes may produce TaN layers having a higher density (e.g., about 13 to 14 g/cm³) compared to the density of TaN layers produced with other methods; for example, thermal atomic layer deposition (ALD) commonly produces TaN layers with a density of about 8 to 9 g/cm³. iALD TaN layers also may have a higher conductivity and lower resistivity than thermal ALD TaN layers. iALD processes may have other advantages, including providing very conformal layers, a precise control of the thickness of these layers, the ability to vary the layer composition, and the ability to engineer the surface of the layer to improve the adhesion of a subsequent layer.

iALD processes use a plasma during the deposition of a material, which may result in damage to dielectrics or other materials on a wafer substrate. For example, when depositing TaN via an iALD process, the pre-cracking of precursors may be required to reduce the TaN nucleation delay. During the pre-cracking step, which is typically about 10 cycles, about 0.3 Angstroms of TaN is deposited per cycle. Each cycle involves a plasma treatment, and a low-k dielectric, for example, on which the TaN is deposited may not be protected from damage by the plasma during these cycles. Avoiding such damage to dielectrics on the wafer substrate is important, as damage to a dielectric may degrade its electrical properties. In the case of back-end metallization, damage to the low-k dielectric may cause the dielectric constant to increase in capacitance, which may result in an increased resistive-capacitive (RC) delay. In the case of front-end metallization, damage to the high-k dielectric at a metal/dielectric interface may cause the metal work function to shift which may result in degraded transistor performance.

### Method

In the disclosed implementations, a protective layer is deposited on a wafer substrate prior to depositing a barrier layer on the wafer substrate using a first plasma-assisted deposition process. In some implementations, a protective layer is deposited on a dielectric on a wafer substrate prior to depositing a TaN layer using an iALD process. The dielectric may be a high-k or a low-k dielectric. High-k dielectrics include zirconium oxide, hafnium oxide, zirconium silicate, and hafnium silicate, for example. Low-k and ultra-low-k dielectrics include carbon doped silicon oxide (SiOC) and low density SiOC based compounds. These dielectric materials may be damaged by bombardment with ions present in the iALD process. The protective layer of the disclosed implementations may serve to protect the underlying dielectric from damage during the first plasma-assisted deposition process.

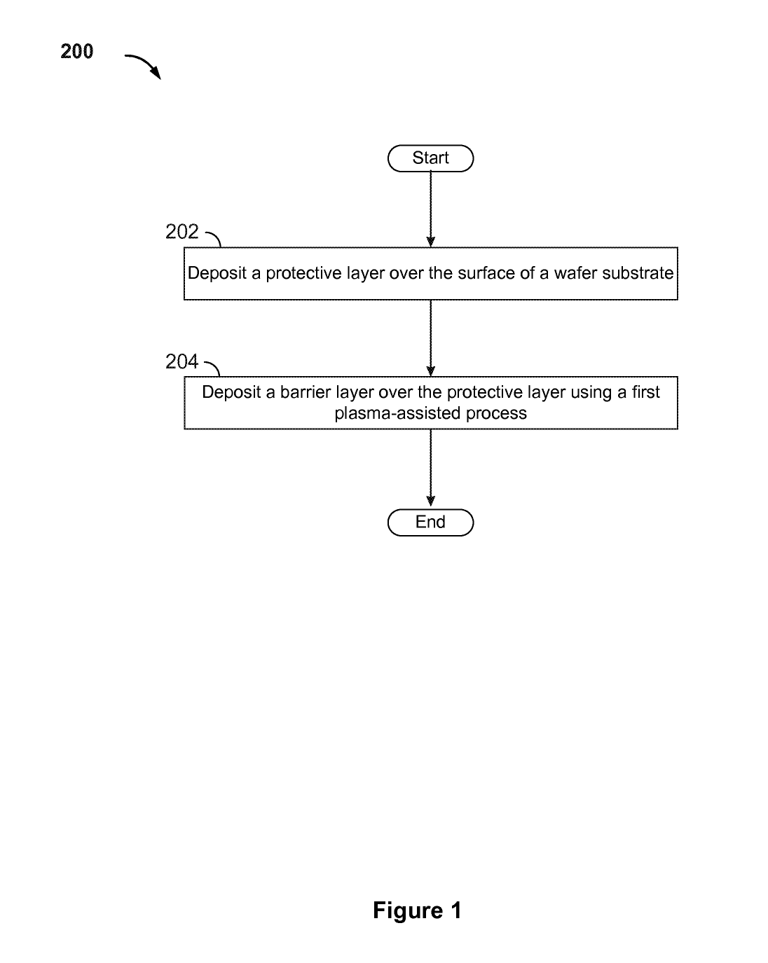

FIG. 1 an example of a flow diagram of a method of depositing a barrier layer. At block 202 of the method 200, a protective layer is deposited on the surface of a wafer substrate. The protective layer may be deposited using a number of different processes. In some implementations, the method of depositing the protective layer may produce substantially less damage to a wafer substrate than a plasma-assisted process such as an iALD process or a PECVD process. The deposition process may yield good step coverage in the features of the wafer substrate. For example, the protective layer may be deposited with a thermal ALD process, a thermal chemical vapor deposition (CVD) process, a low-power PECVD process, a remote-plasma PECVD process, or a sputtering process.

In some implementations the protective layer may be deposited with a thermal ALD process. Thermal ALD processes are usually performed with two different chemicals or precursors and are based on sequential, self-limiting surface reactions. The precursors are sequentially admitted to a reaction chamber in a gaseous state where they contact the surface of the wafer substrate. For example, a first precursor is adsorbed onto the surface when it is admitted to a reaction chamber. Then, the first precursor reacts with a second precursor at the surface when the second precursor is admitted to the reaction chamber. By repeatedly exposing a surface to alternating sequential pulses of the precursors, a thin film of the protective material is deposited. Thermal ALD processes also include processes in which a surface is exposed to sequential pulses of a single precursor, which also may deposit a thin film of the protective material on the surface. Thermal ALD generally forms a conformal layer, i.e., a layer that faithfully follows the contours of the underlying surface. By exposing the precursors to a surface repeatedly, a thin protective layer may be deposited. The final thickness of the protective layer depends on the thickness of the precursor absorption layer as well as the number of precursor exposure cycles. A general description of thermal ALD processes and apparatus is given in U.S. Pat. No. 6,878,402, which is herein incorporated by reference.

For example, in some implementations, the protective layer may be deposited with a thermal ALD process at about 200° C. to 550° C. The process sequence may include the operations of a first precursor dose, a first precursor purge, a second precursor dose, and a second precursor purge. Each operation may be performed over a time period of about 0.1 seconds to 30 seconds at pressures of about 0.01 Torr to 200 Ton.

Table I lists process conditions for an implementation of a thermal ALD process for depositing a TaN protective layer. An inert carrier gas, such as argon (Ar), helium (He), or nitrogen (N₂), may be used to aid in transport of the tantalum precursor to the reaction chamber. The TaN protective layer may be deposited at a temperature of about 300° C. to 320° C.

In general, a precursor for depositing a TaN protective layer using a thermal ALD process may be any tantalum-containing species that can be provided in gaseous phase, that can form a saturated layer on the surface of interest, and that can be reduced to form tantalum metal or tantalum nitride on the surface of a substrate under available thermal ALD process conditions. The precursor may be a gas at room temperature, or may be a liquid or solid heated to a temperature high enough to provide sufficient vapor pressure for delivery to the substrate with an inert carrier gas. In some implementations the tantalum precursor is a tantalum halide such as TaF₅, TaCl₅, TaBr₅, or TaI₅. Tantalum halides can be used to generate TaN or metallic Ta. However, halides should be used with caution as the halogen generated during the deposition process can react with the underlying layer, which is not desirable. Examples of a thermal ALD process for the deposition of tantalum nitride using a tantalum halide precursor are given in U.S. Pat. No. 7,144,806, which is herein incorporated by reference.

In other implementations the tantalum precursor is terbutylimido-tris(diethylamino)tantalum (TBTDET). Further implementations use other tantalum-amine complexes for a tantalum precursor, including pentakis(dimethylamino)tantalum (PDMAT), t-butylamino-tris(diethylamino)tantalum (TDBDET), pentakis(diethylamido)tantalum (PDEAT), pentakis(ethylmethylamido)tantalum (PEMAT), and imidotris(dimethylamido)tantalum (TAIMATA). These tantalum precursors all contain nitrogen. When using one of these precursors, Ta(C)(N) layers can be formed if a reducing agent such hydrogen is used. The use of a nitrogen-containing reducing agent may generate a nitrogen-rich TaN layer. Nitrogen-containing reducing reagents include ammonia, mixtures of hydrogen and ammonia, and amines (e.g, triethyl amine, trimethyl amine), for example. Other tantalum-containing precursors also may be used to deposit a TaN protective layer.

TABLE I
Process conditions for an implementation of a thermal
ALD process for depositing a TaN protective layer.

| | Precursor | Ar | NH₃ | Time | Pressure |
|---|---|---|---|---|---|
| | (sccm) | (sccm) | (sccm) | (s) | (Torr) |
| Precursor dose | 300 | 1000 | | 0.5 to 1 | 2 to 5 |
| Precursor Purge | | 2000 | | 1 to 2 | 2 to 5 |
| NH₃ dose | | 150 | 500 | 0.5 to 1 | 2 to 5 |
| NH₃ purge | | 2000 | | 1 to 2 | 2 to 5 |

In some other implementations, the protective layer may be deposited using a low-power PECVD process. In low-power PECVD processes, a radio frequency (RF) power is applied to sustain a plasma discharge when depositing a protective layer, in some implementations. A dual frequency PECVD system with both high and low frequency radio power supplies can also be used. Low-power PECVD processes utilize a plasma to enhance chemical reaction rates of the precursors. Some low-power PECVD processes allow for the deposition of a material using a low-power RF power, which may result in little of no damage to an exposed dielectric layer on a wafer substrate surface.

In some implementations in which the protective layer is deposited using a low-power PECVD process, the plasma is a low-power plasma. The RF power used to generate the plasma may be applied at a power of less than about 100 Watts (W) for a 300 millimeter wafer substrate, in some implementations. In some implementations, the RF power used to generate the plasma may be about 25 W to 150 W. In some implementations, the RF power used to generate the plasma may be about 50 W. A general description of PECVD processes and apparatus in which a low-power plasma may be used is given in U.S. patent application Ser. No. 12/070,616, entitled “PLASMA PARTICLE EXTRACTOR FOR PECVD,” and filed Feb. 19, 2008, which is herein incorporated by reference. In some implementations, the protective layer may be deposited with a low-power PECVD process at about 150° C. to 550° C. The process sequence may include the operations of a precursor dose, a precursor purge, a plasma exposure, and a post-plasma purge. Each operation may be performed over a time period of about 0.1 seconds to 30 seconds at pressures of about 0.01 Torr to 200 Torr.

For example, a protective layer of TaN may be deposited with a low-power PECVD process. A precursor dose is first admitted to the process chamber. During the precursor dose, the precursor is dissociated with a low-power plasma. In some implementations, the plasma is generated with about 50 W of RF power. The precursor adsorbs to the wafer substrate surface. The excess precursor (i.e., the precursor that is not adsorbed onto the wafer substrate surface) may then be purged from the process chamber. In some implementations, a mixture of argon and hydrogen gasses may be used to purge the excess precursor from the process chamber. A plasma generated with the argon and hydrogen forms argon ions and hydrogen radicals. The argon ions provide energy to induce a chemical reaction between the adsorbed tantalum precursor and the hydrogen precursor, forming a monolayer of TaN. Finally, the chamber may be purged to any remove chemical byproducts. This process may be repeated until the desired thickness of the protective layer of TaN is formed. Table II lists process conditions (i.e., time for each step in the process and the associated RF power) for an implementation of a low-power PECVD process for depositing a TaN protective layer. In some implementations, the low-power PECVD process is performed with increased precursor dose times and increased plasma treatment times. The same tantalum precursors used in thermal ALD processes, listed above, also may be used in low-power PECVD processes. An inert carrier gas, such as argon (Ar), helium (He), or nitrogen (N₂), may be used to aid in transport of the precursor to the reaction chamber.

TABLE II
Process conditions for one implementation of a low-power PECVD
process for depositing a TaN protective layer.

| | RF power | Time |
|---|---|---|
| | (W) | (s) |
| Precursor dose | 50 | 0.5 |
| Purge | 50 | 0.5 |
| Plasma exposure | 50 | 2 |
| Post-plasma purge | 50 | 0.1 |

In some implementations, the protective layer may be deposited using a remote-plasma PECVD process or a remote-plasma ALD process. In a remote-plasma PECVD process or a remote-plasma ALD process, the plasma may be generated with a remote plasma source. The use of a plasma generated with a remote-plasma source may minimize or substantially eliminate damage to the wafer substrate that may be caused by a plasma. Remote-plasma PECVD processes and remote-plasma ALD processes are similar to direct PECVD processes except that the work piece (e.g., the wafer substrate) is not directly in the plasma source region. The plasma source is upstream from the wafer substrate, and activates and/or disassociates precursor species to form reactive ions and radicals. Reducing gasses, including ammonia and hydrogen, are also dissociated into reactive ions and radicals within the remote plasma source in some implementations. In some implementations a showerhead and a faceplate can be used to filter out ions such that only radicals reach the wafer substrate surface. Radicals may cause little damage to an ultra-low-k dielectric. Further, removing the wafer substrate from the area of the plasma source may allow for processing temperatures down to about room temperature. A general description of remote-plasma PECVD processes and apparatus is given in U.S. Pat. No. 6,616,985 and U.S. Pat. No. 6,553,933, both of which are herein incorporated by reference. As noted above, a remote-plasma source also may be used in ALD-type processes for the deposition of a protective layer in some implementations.

As noted herein, in some implementations, the protective layer may be TaN. TaN used as a protective layer contributes to the barrier layer properties of TaN subsequently deposited by iALD. In some other implementations, the protective layer may be a layer of another material, for example, a layer of a metal (e.g., ruthenium (Ru), titanium (Ti), or tungsten (W)), a layer of a metal nitride (e.g., titanium nitride (TiN) or tungsten nitride(WN)), or a layer of a metal carbide.

In some implementations, the protective layer may be at least about one monolayer thick. In implementations where TaN is used for the protective layer, the TaN layer may be at least about 3 Angstroms thick. In some other implementations the protective layer may be about 3 to 30 Angstroms thick or about 5 Angstroms thick. In some implementations the protective layer may be about 40, 50, or even 100 Angstroms thick. It is believed that one monolayer of the protective layer may be sufficient to prevent damage to an underlying dielectric during subsequent iALD processes. If the protective layer is too thick, there may not be room in the feature into which iALD TaN and Cu, for example, may be deposited.

Returning to the method 200 shown in FIG. 1, at block 204, a barrier layer is deposited over the protective layer using a first plasma-assisted process. Plasma-assisted processes include iALD and PECVD processes. iALD and PECVD processes may use plasmas generated with greater than about 300 W RF power or about 350 to 450 W of RF power. In some implementations, the barrier layer may be TaN, tantalum (Ta), tungsten (W), titanium (Ti), titanium nitride (TiN), titanium nitride silicon (TiNSi), or the like. In some implementations, the combined thickness of the protective layer and the barrier layer may be about 5 to 50 Angstroms thick.

For example, in some implementations, an iALD process may be used to deposit a TaN barrier layer. For an iALD TaN layer deposited on a thermal ALD TaN protective layer, for example, a pre-cracking process (described above) is not required, removing this source of possible damage to the wafer substrate.

To deposit a TaN barrier layer, a precursor dose is first admitted to the process chamber. The precursor may chemically adsorb onto the wafer substrate surface. In some implementations, the precursor may form about a monolayer of coverage on the wafer substrate surface. The precursors used in the thermal ALD process for TaN deposition, described above, may be used in the iALD processes. Excess precursor (i.e., the precursor that is not adsorbed onto the wafer substrate surface) may be purged from the process chamber. In some implementations, a mixture of argon and hydrogen gasses may be used to purge the excess precursor from the process chamber. RF power may be applied to the argon and hydrogen gasses, forming argon ions and hydrogen radicals. The argon ions provide energy to induce a chemical reaction between the adsorbed tantalum precursor and the hydrogen precursors, forming a monolayer of TaN. Finally, the process chamber may be purged to remove any chemical byproducts. This process may be repeated until the desired thickness of the iALD TaN barrier layer is formed. Table III lists process conditions (i.e., time for each step in the process and the associated RF power) for a specific implementation of an iALD process for depositing a TaN barrier layer.

TABLE III
Process conditions for one implementation of an iALD process
for depositing a TaN barrier layer.

| | RF power | Time |
|---|---|---|
| | (W) | (s) |
| Precursor dose | 0 | 0.5 |
| Purge | 0 | 0.5 |
| Plasma on | 450 | 2 |
| Post plasma purge | 0 | 0.1 |

In some implementations, the protective layer and the barrier layer are deposited on the wafer substrate using the same processing tool; i.e., the same process chamber is used for both deposition processes. Depositing both the protective layer and the barrier layer using the same processing tool may increase the throughput for the processing tool and decrease cost, in some implementations. In various implementations, the protective layer and the barrier layer may have the same, or nearly the same, composition, with the protective layer being deposited by a one process and the barrier layer being deposited by iALD or PECVD.

As noted above, iALD TaN layers generally have a higher density and a higher conductivity than thermal ALD TaN layers. Further, iALD processes may allow for the formation of layers with composition modulations; these composition modulations may be generated by the plasma species in the iALD process in some implementations. With the ability to control the composition of a TaN layer deposited with an iALD process, the composition of the surface of the TaN layer may be tailored to improve the adhesion of subsequent materials deposited on the TaN layer. For example, when copper is subsequently deposited on the TaN layer, the surface of the TaN layer may be Ta rich, which would improve the copper adhesion. This may obviate the need to deposit a metallic Ta layer on the TaN barrier layer, which is sometimes included to improve the adhesion of copper.

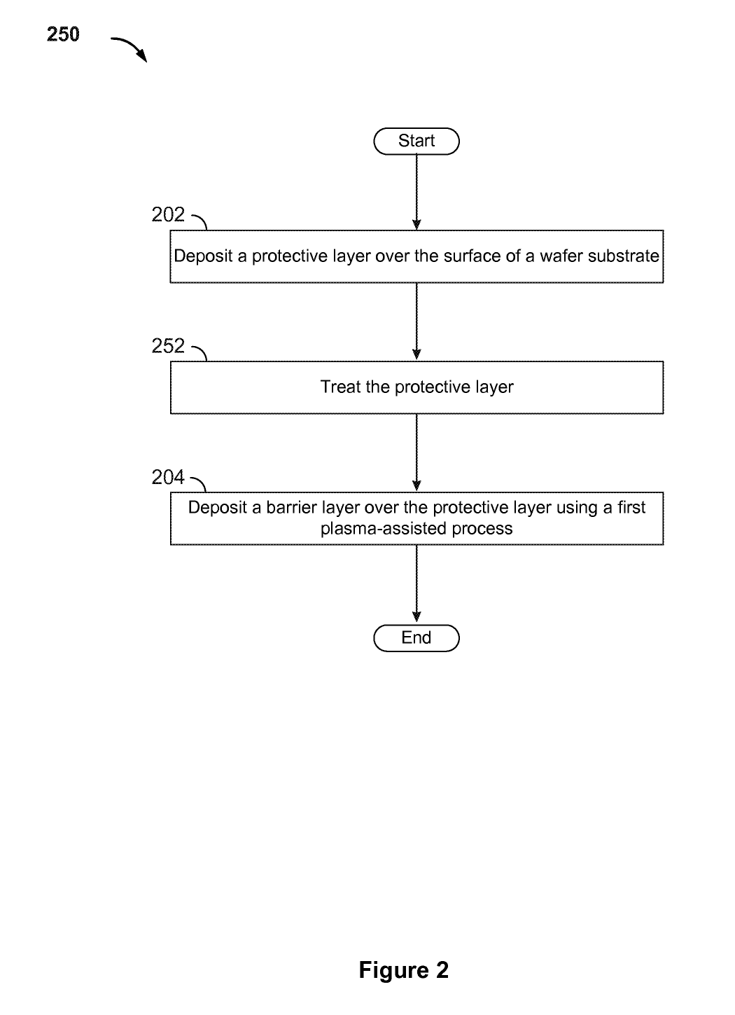

FIG. 2 shows an example of a flow diagram of a method of depositing a barrier layer. Implementations of the method 250 shown in FIG. 2 may be similar to the method 200 shown in FIG. 1, with the addition of block 252. At block 252, after the operation of depositing a protective layer over a surface of a wafer substrate at block 202, the protective layer is treated. The protective layer treatment may increase the density the protective layer or adhesion of the barrier layer to the protective layer, for example. Examples of protective layer treatments include exposing the protective layer to elevated temperatures (i.e., a thermal anneal), to a plasma or species from a remote plasma (e.g., to increase the density of the protective layer), to a reducing atmosphere (e.g., an atmosphere of argon and ammonia or an atmosphere of hydrogen and ammonia), or to the vacuum of the process chamber in which the protective layer was deposited.

In one experiment, a protective layer combined with an iALD deposited barrier layer was used in one semiconductor device fabrication process (process 1) and a PVD deposited barrier layer was used in another semiconductor device fabrication process (process 2). In process 1, a 5 Angstrom thick protective layer of TaN was deposited on a semiconductor dual damascene structure using a thermal ALD process, and then a 5 Angstrom thick layer of TaN was deposited on the protective layer using an iALD process. A Ta flash layer was deposited using a physical vapor deposition (PVD) process. In process 2, a TaN layer was deposited using a PVD process. After depositing the TaN layer, a Ta flash layer was deposited using a PVD process. For the structures formed by process 1 and process 2, a Cu layer was deposited using a PVD processes, and Cu was then plated. The Cu over burden was removed using chemical-mechanical planarization (CMP). General semiconductor processes were used to complete the fabrication of the dual damascene device.

The Kelvin via resistance of the device formed using process 1 and the device formed with process 2 were then measured. While the TaN protective layer has a high resistivity, the use of the TaN protective layer does not result in a high Kelvin via resistance. This may be due to electron tunneling though the thin protective layer.

### Apparatus

Another aspect of the implementations disclosed herein is an apparatus configured to accomplish the methods described herein. A suitable apparatus includes hardware for accomplishing the process operations and a system controller having instructions for controlling process operations in accordance with the disclosed implementations. Hardware for accomplishing the process operations includes ALD processing chambers, iALD processing chambers, and PECVD processing chambers. The system controller will typically include one or more memory devices and one or more processors configured to execute the instructions so that the apparatus will perform a method in accordance with the disclosed implementations. Machine-readable media containing instructions for controlling process operations in accordance with the disclosed implementations may be coupled to the system controller.

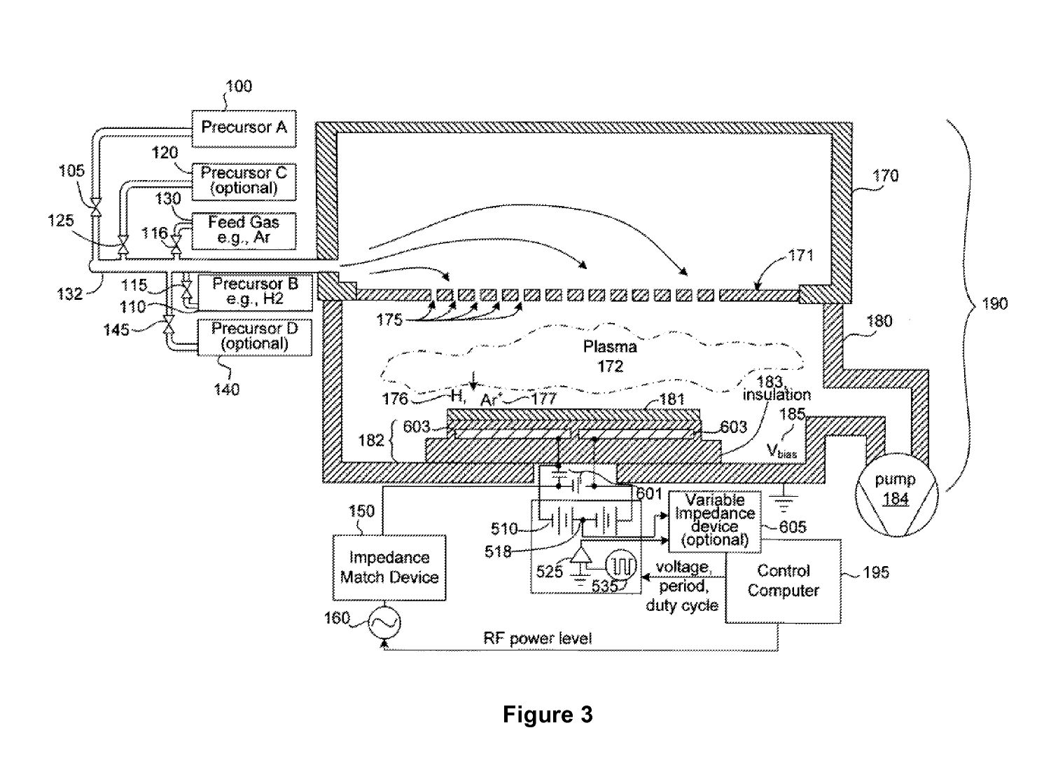

FIG. 3 shows a schematic diagram of a system suitable for atomic layer deposition (ALD) and ion-induced atomic layer deposition (iALD) processes. In the system of FIG. 3, all of the ion/radical generating feed gases and the precursor gases are introduced into a main body chamber 190 via a distribution showerhead 171 including of a series of arrays or apertures 175. However, other means for uniformly distributing gases essentially parallel or perpendicular to a face of a substrate 181 may also be used. Although the showerhead 171 is shown to be above the substrate 181 to direct a gas flow downwards towards the substrate 181, alternative lateral gas introduction schemes are possible. Various lateral gas introduction schemes are described in U.S. patent application Ser. No. 10/215,711, filed Aug. 8, 2002, which is herein incorporated by reference.

In the implementation of the system shown in FIG. 3, a source of RF bias power 160 is coupled to one or more electrostatic chuck (ESC) electrodes 603 in a substrate pedestal 182, which includes insulation 183, via an impedance matching device 150. The ESC electrodes 603 may be of any arbitrary shape. The RF bias power provides power for both ion generation during iALD and energy control of the generated ions. The applied RF bias power is used to generate a plasma 172 in a main process chamber 180, for example, between the substrate 181 and the showerhead 171 to dissociate feed gasses 110 and 130 to generate ions 177 and radicals 176 and to induce a negative potential V_{bias} 185 (i.e., a DC offset voltage typically about −10 V to −80 V at less than or equal to about 475 W RF power and about 0.1 to 5 Ton pressure) on the substrate 181. The negative potential V_{bias} 185 modulates the energy of the positively charged ions in the plasma and attracts the positively charged ions toward the surface of the substrate. The positively charged ions impinge on the substrate 181, driving the deposition reaction and improving the density of the deposited film. The ion energy is more specifically given by E=e|Vₚ|+e|V_{bias}|, where Vₚ is the plasma potential (typically about 10 V to 20 V) and V_{bias} is the negative potential V_{bias} 185 induced on the substrate 181. The negative potential V_{bias} 185 is controlled by the applied RF bias power. For a given process region geometry, the induced negative potential V_{bias} 185 increases with increasing RF bias power and decreases with decreasing RF bias power.

Controlling the RF bias power also controls the density and hence the number of ions generated in the plasma. Increasing the RF bias power generally increases the ion density, leading to an increase in the flux of ions impinging on the substrate. Higher RF bias powers are also required for larger substrate diameters. In some processes, a power density less than or equal to about 0.5 W/cm² may be used, which equates to less than or equal to about 150 W for an about 200 mm diameter substrate. Power densities greater than or equal to about 3 W/cm² (i.e., greater than about 1000 W for a 200 mm diameter substrate) may lead to undesired sputtering of the deposited film.

The frequency of the RF bias power can be about 400 kHz, about 13.56 MHz, or higher (e.g., about 60 MHz, etc.). A low frequency (e.g., about 400 kHz), however, can lead to a broad ion energy distribution with high energy tails which may cause excessive sputtering. The higher frequencies (e.g., about 13.56 MHz or greater) may lead to tighter ion energy distributions with lower mean ion energies, which may be favorable for iALD processes. The more uniform ion energy distribution occurs because the RF bias polarity switches before ions can impinge on the substrate, such that the ions see a time-averaged potential.

As shown in FIG. 3, a source of applied DC bias can also be coupled to the ESC substrate pedestal 182. The source can be a DC power supply 510 coupled by a center tap 518 to a voltage source 525 with the ability to vary the voltage or exhibit an infinite impedance. Optionally, a variable impedance device 605 may be coupled in series between the voltage source 525 and the center tap 518 of the DC power supply 510. The voltage source 525 is itself coupled to a waveform generator 535. The waveform generator may be a variable-type waveform generator. A variable-type waveform generator may be controlled by a control computer 195 and have a variable waveform at different times within a given process and may additionally have a non-periodic output signal. The source of applied DC bias can be coupled to the ESC substrate pedestal 182 by RF blocking capacitors 601 that both provide a DC open for the DC power supply 510 and prevent RF energy from corrupting the DC power supply 510.

In iALD, the same plasma is used to generate both ions 177 (used to drive the surface reactions) and radicals 176 (used as the second reactant). The iALD system utilizes ion imparted kinetic energy transfer rather than thermal energy to drive the deposition reaction. Since temperature can be used as a secondary control variable, with this enhancement films can be deposited using iALD at arbitrarily low substrate temperatures (generally less than about 350° C.). In particular, films can be deposited at or near room temperature (i.e., about 25° C.) or below.

The system of FIG. 3 contains a substantially enclosed chamber 170 located in substantial communication with or substantially within a main chamber body 190. The feed gasses 110 and 130 are delivered to the plasma source chamber 170 via valving 115 and 116, and a gas feed line 132. Typical feed gases 130 used for ion generation include, but are not restricted to, Ar, Kr, Ne, He, and Xe. Typical feed gases 110 (e.g., precursor B) used for radical generation include, but are not restricted to H₂, 0₂, N₂, NH₃, and H₂O vapor. The ions 177 are used to deliver the energy needed to drive surface reactions between the first adsorbed reactant and the generated radicals 176.

Gaseous reactants 100 (e.g., precursor A), 120 (e.g., precursor C), and 140 (e.g., precursor D) may be used to form a desired layer. The first reactant 100 (e.g., precursor A) may be introduced to the chamber 170 via valving 105 and the gas feed line 132. The second reactant 120 (e.g., precursor C) may be introduced to the chamber 170 via valving 125 and the gas feed line 132. The third reactant 140 (e.g., precursor D) may be introduced to the chamber 170 via valving 145 and the gas feed line 132. The chamber 180 may be evacuated with a vacuum pump 184. iALD systems and methods are further described in U.S. Pat. No. 6,416,822 and U.S. Pat. No. 6,428,859.

### Further Implementations

The apparatus/processes described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a work piece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper.

What is claimed is:

1. A method comprising:
(a) depositing a protective layer over a surface of a wafer substrate using a process configured to produce substantially less damage in the wafer substrate than a first plasma-assisted deposition process, wherein the protective layer is less than about 100 Angstroms thick; and
(b) depositing a barrier layer over the protective layer using the first plasma-assisted deposition process.

2. The method of claim 1, wherein the protective layer is about one monolayer thick.

3. The method of claim 1, wherein the protective layer is about 3 to 30 Angstroms thick.

4. The method of claim 1, wherein the first plasma-assisted deposition process uses a plasma generated with greater than about 300 watts radio frequency power.

5. The method of claim 1, wherein the protective layer includes a metal.

6. The method of claim 1, wherein the protective layer includes tantalum nitride.

7. The method of claim 1, wherein the barrier layer includes tantalum nitride.

8. The method of claim 1, wherein operations (a) and (b) are performed in the same process chamber.

9. The method of claim 1, wherein operation (a) includes a thermal atomic layer deposition process.

10. The method of claim 1, wherein operation (a) includes a chemical vapor deposition process employing a low-power plasma.

11. The method of claim 1, wherein operation (a) includes a chemical vapor deposition process employing a remote plasma source or an atomic layer deposition process employing a remote plasma source.

12. The method of claim 1, wherein the surface of the wafer over which the protective layer is deposited includes a dielectric.

13. The method of claim 12, wherein the dielectric is a low-k dielectric.

14. The method of claim 12, wherein the dielectric is a high-k dielectric.

15. The method of claim 1, further comprising:
after operation (a) but before operation (b), treating the protective layer.

16. The method of claim 1, wherein the first plasma-assisted deposition process includes an ion-induced atomic layer deposition process.

17. The method of claim 1, further comprising:
applying photoresist to the wafer substrate;
exposing the photoresist to light;
patterning the resist and transferring the pattern to the wafer substrate; and
selectively removing the photoresist from the wafer substrate.

18. An apparatus comprising:
(a) a process chamber; and
(b) a controller comprising program instructions for conducting a process comprising the steps of:
depositing a protective layer over a surface of a wafer substrate using a process configured to produce substantially less damage in the wafer substrate than a first plasma-assisted deposition process, wherein the protective layer is less than about 100 Angstroms thick; and
depositing the barrier layer over the protective layer using the first plasma-assisted deposition process.

19. A system comprising the apparatus of claim 18 and a stepper.

20. A non-transitory computer machine-readable medium comprising program instructions for control of a deposition apparatus, the instructions comprising code for:
depositing a protective layer over a surface of a wafer substrate using a process configured to produce substantially less damage in the wafer substrate than a first plasma-assisted deposition process, wherein the protective layer is less than about 100 Angstroms thick; and
depositing a barrier layer over the protective layer using the first plasma-assisted deposition process.
